(19) United States
(12) Patent Application Publication
(10) Pub. No.: US 2021/0008545 A1
(43) Pub. Date: Jan. 14, 2021

(54) LIQUID HANDLING DEVICE

(71) Applicant: Enplas Corporation, Saitama (JP)

(72) Inventors: Yuya OSHIMA, Saitama (JP); Nobuya SUNAGA, Saitama (JP)

(73) Assignee: Enplas Corporation, Saitama (JP)

(21) Appl. No.: 16/976,769

(22) PCT Filed: Feb. 25, 2019
(86) PCT No.: PCT/JP2019/007076

§ 371 Date: Aug. 31, 2020

(30) Foreign Application Priority Data
Mar. 1, 2018 (JP) 2018-036453

(51) Int. Cl. B01L 3/02; B81B 1/00; G01N 35/08

(52) U.S. Cl. CPC B01L 3/0241; B81B 1/00; B81B 2203/0338; B81B 2201/057; G01N 35/08

(57) ABSTRACT

This liquid handling device includes: a first flow passage through which a first liquid can flow; a second flow passage through which a second liquid can move; a third flow passage through which the second liquid can move; and a droplet generating unit, which is a merging portion of the second flow passage and the third flow passage with respect to the first flow passage, and which is configured in such a way that the first liquid flowing through the first flow passage is divided in the form of droplets by means of the second liquid flowing through the second flow passage and the third flow passage.

### TECHNICAL FIELD

The present invention relates to a liquid handling device.

### BACKGROUND ART

Liquid handling devices are known in analyses such as clinical analyses, food analyses and environmental analyses for analyzing minute amounts of a analyte such as cells, proteins or nucleic acids with high precision. Known is, for example, a liquid handling device that handles minute liquid drops (hereinafter, also referred to as “droplets”) having a diameter of 0.1 to 1,000μm generated from a liquid containing the analyte (see, for example, Non-Patent Literature (hereinafter also referred to as “NPL”) 1). In such a liquid handling device, a channel in which a second liquid flows joins a channel in which a first liquid containing the analytes flows, and the second liquid divides the first liquid containing the analytes, thus generating a droplet.

### CITATION LIST

### Non-Patent Literature

NPL 1

C. Wyatt Shields IV, et al., Microfluidic cell sorting: a review of the advances in the separation of cells from debulking to rare cell isolation, Lab on a Chip, Vol. 15, pp.1230-1249

### SUMMARY OF INVENTION

### Technical Problem

Droplets are typically generated from a liquid diluted in such a way that at most one analyte is contained in each droplet. The number of analytes contained in individual droplets follows a probability distribution called Poisson distribution. Even when droplets are generated from a liquid diluted in such a way that at most one analyte is contained in each droplet as described above, empty droplets that do not contain analytes and droplets that contain more than one analyte may be generated depending on the size of the generated droplets. In the liquid handling device with a channel in which a second liquid flows joining a channel in which a first liquid containing the analytes flows, for example, increase of the flow rate of the second liquid leads to decrease of the size of the droplets, and as a result, empty droplets are more likely to be generated. On the contrary, decrease of the flow rate of the second liquid leads to increase of the size of the droplets, and as a result, droplets containing more than one analyte are more likely to be generated. The size of the droplets may change without highly precise control of the flow rate of the second liquid, and thus empty droplets or droplets containing more than one analyte are more likely to be generated. Such empty droplets or droplets containing more than one analyte decrease the accuracy of the analysis or increase the time required for the analysis, and thus are not preferred.

The present invention has been made under the above circumstances, and an object of the present invention is to provide a liquid handling device capable of stably generating droplets of a desired size even when the flow rate of a liquid changes to some extent.

### Solution to Problem

The liquid handling device according to the present invention includes a first channel that allows a first liquid to flow through; a second channel that allows a second liquid to move through, the second channel joining the first channel; a third channel that allows the second liquid to move through, the third channel joining the first channel; and a droplet generator configured such that the second liquid flowing in the second channel and the third channel divides the first liquid flowing in the first channel into droplets, the droplet generator being a junction of the second channel and the third channel with the first channel, in which: the second channel and the third channel each include a main channel and a sub channel on a downstream side, an opening of the main channel of the second channel with respect to the first channel is disposed to face an opening of the main channel of the third channel with respect to the first channel, and an opening of the sub channel of the second channel with respect to the first channel is disposed to face an opening of the sub channel of the third channel with respect to the first channel.

### Advantageous Effects of Invention

The present invention provides a liquid handling device capable of stably generating droplets of a desired size even when the flow rate of a liquid changes to some extent.

### BRIEF DESCRIPTION OF DRAWINGS

FIGS. 1A and 1B illustrate a liquid handling device according to an embodiment of the present invention;

FIGS. 2A and 2B are partially enlarged views illustrating an example of a droplet generator of the liquid handling device;

FIGS. 3A and 3B are partially enlarged views illustrating examples of the droplet generator of the liquid handling device; FIG. 4A is a graph showing changes in the size of droplets generated when the widths of the openings of the main channels of the second channel and the third channel and the sub channels of the second channel and the third channel are changed, and FIG. 4B is a graph showing changes in the size of the droplets generated when the width of a first channel at a junction of the first channel with the main channels of the second channel and the third channel, and the widths of the first channel at individual junctions of the first channel with the sub channels of the second channel and the third channel are changed;

FIG. 5A is a graph showing changes in the size of the droplets generated when the number of the sub channels of the second channel and the third channel are changed, and FIG. 5B is a graph showing changes in the size of droplets generated when the distances between the sub channels in the individual second channel and third channel are changed; and

FIG. 6 is a graph showing changes in the size of droplets generated when a surfactant is added to a first liquid flowing in the first channel.

### DESCRIPTION OF EMBODIMENTS

Hereinafter, an embodiment of the present invention will be described in detail with reference to the drawings. In the following description, the “cross-sectional area of a channel” means the area of the cross section orthogonal to the flow direction of the channel.

(Configuration of Liquid Handling Device)

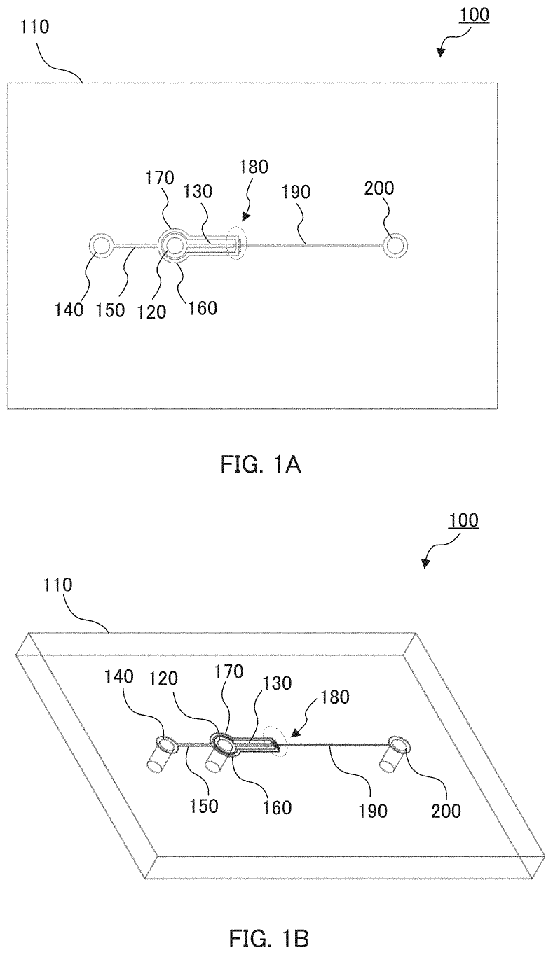

FIG. 1A is a plan view of liquid handling device 100 according to an embodiment of the present invention, and FIG. 1B is a perspective view of liquid handling device 100. These drawings omit films to illustrate channels.

Liquid handling device 100 includes substrate 110 having through holes and grooves formed therein, and a film (not shown) disposed on one surface of substrate 110 so as to block the openings of the through holes and grooves. As described below, blocking one of the openings of each through hole formed in substrate 110 with the film forms first liquid inlet 120, second liquid inlet 140 or droplet outlet 200 (all of which will be described below). In addition, blocking the opening of each groove formed in substrate 110 with the film forms first channel 130, second liquid common channel 150, second channel 160, third channel 170, droplet generator 180 and droplet channel 190 (all of which will be described below).

As illustrated in FIGS. 1A and 1B, liquid handling device 100 includes first liquid inlet 120, first channel 130, second liquid inlet 140, second liquid common channel 150, second channel 160, third channel 170, droplet generator 180, droplet channel 190 and droplet outlet 200.

First liquid inlet 120 is a bottomed recess for housing a first liquid that is to become droplets. First liquid inlet 120 is formed, as described above, by blocking with a film one of the openings of the through hole formed in substrate 110. First liquid inlet 120 is connected to first channel 130. First liquid inlet 120 may have any shape and size as long as a first liquid can be introduced into first liquid inlet 120 from the outside. Examples of the shape of first liquid inlet 120 include a cylindrical shape and a truncated cone shape. First liquid inlet 120 has a cylindrical shape in the present embodiment.

The type of first liquid introduced from first liquid inlet 120 is not limited. The first liquid is, for example, a liquid containing an analyte such as cells, nucleic acids (for example, DNA or RNA) or proteins (for example, enzymes). The dispersion medium or solvent of the analyte in the liquid is not limited as long as it can disperse or dissolve the analyte, and is, for example, water, a buffer solution or physiological saline. The first liquid may also be, for example, blood, plasma, serum or a diluted solution thereof.

First channel 130 is a channel for guiding the first liquid introduced from first liquid inlet 120 to droplet generator 180. The upstream end of first channel 130 is connected to first liquid inlet 120, and the downstream end of first channel 130 is connected to droplet generator 180. The downstream end of first channel 130 is considered to form a part of droplet generator 180. First channel 130 may have any shape. First channel 130 is linear in the present embodiment. The cross-sectional area of first channel 130 is not limited, and may be set appropriately according to the size of droplets to be generated. The width of first channel 130 is, for example, about 30μm to 100μm. The depth of first channel 130 is, for example, about 30μm to 100μm.

Second liquid inlet 140 is a bottomed recess for housing a second liquid that is used to divide the first liquid into droplets. Second liquid inlet 140 is formed, as described above, by blocking with a film one of the openings of the through hole formed in substrate 110. Second channel 160 and third channel 170 are connected to second liquid inlet 140 via second liquid common channel 150. That is, second channel 160 and third channel 170 are connected to the same second liquid inlet 140 (connected to one second liquid inlet 140). Second liquid inlet 140 may have any shape and size as long as a second liquid can be introduced into second liquid inlet 140 from the outside. Examples of the shape of second liquid inlet 140 include a cylindrical shape and a truncated cone shape. Second liquid inlet 140 has a cylindrical shape as first liquid inlet 120 has in the present embodiment.

The type of second liquid to be introduced from second liquid inlet 140 may be selected appropriately according to the type of first liquid. The second liquid also functions as a dispersion medium for the droplets of the first liquid, and thus any liquid that is incompatible with the first liquid and does not denature the first liquid is preferred. When the first liquid is blood, for example, the second liquid is any of various oils that are liquid at room temperature, such as mineral oil and silicone oil. The second liquid may be an oil having a surfactant added therein.

Second liquid common channel 150 guides the second liquid introduced from second liquid inlet 140 to second channel 160 and third channel 170. Directly connecting second channel 160 and third channel 170 to second liquid inlet 140 can make second liquid common channel 150 unnecessary. The upstream end of second liquid common channel 150 is connected to second liquid inlet 140, and the downstream end of second liquid common channel 150 is connected to the upstream ends of second channel 160 and third channel 170. Second liquid common channel 150 may have any shape. Second liquid common channel 150 is linear in the present embodiment. The width and depth of second liquid common channel 150 are not limited, either.

Second channel 160 and third channel 170 guide the second liquid introduced from second liquid inlet 140 to droplet generator 180. In the present embodiment, the upstream ends of second channel 160 and third channel 170 are connected to the downstream end of second liquid common channel 150, and the downstream ends of second channel 160 and third channel 170 are connected to droplet generator 180. The downstream ends of second channel 160 and third channel 170 are considered to form a part of droplet generator 180. As described below, second channel 160 and third channel 170 join first channel 130 at droplet generator 180. Second channel 160 and third channel 170 may have any shape. In the present embodiment, second channel 160 and third channel 170 are disposed so as to surround first liquid inlet 120 and first channel 130, and second channel 160 opens to one side surface of first channel 130, and third channel 170 opens to the other side surface of first channel 130.

As will be described later, the downstream part of second channel 160 branches into main channel 161 and one or more sub channels 162 to 164. The downstream part of third channel 170 similarly branches into main channel 171 and one or more sub channels 172 to 174.

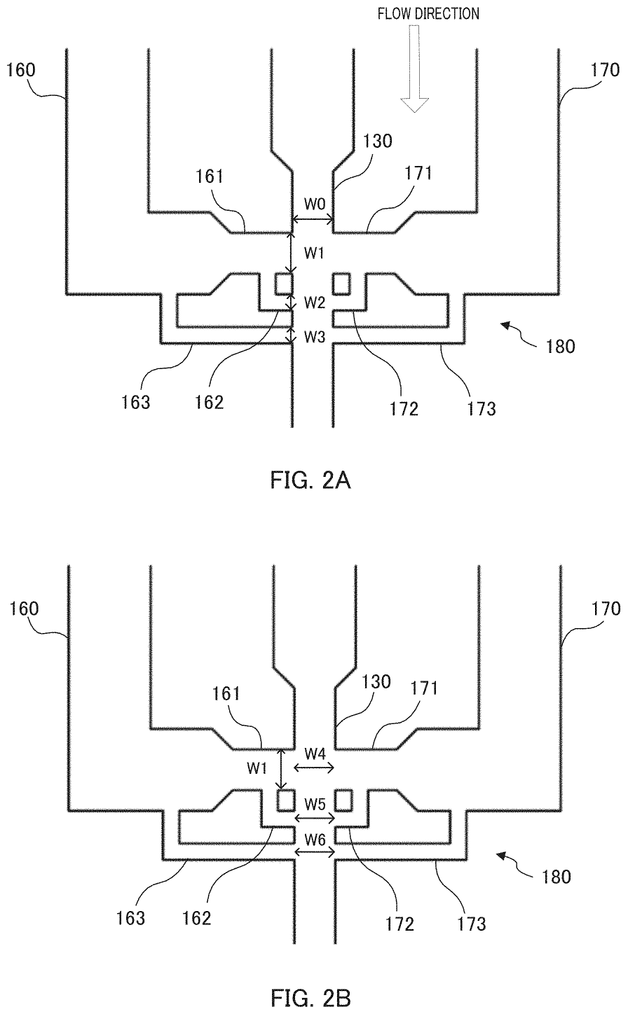

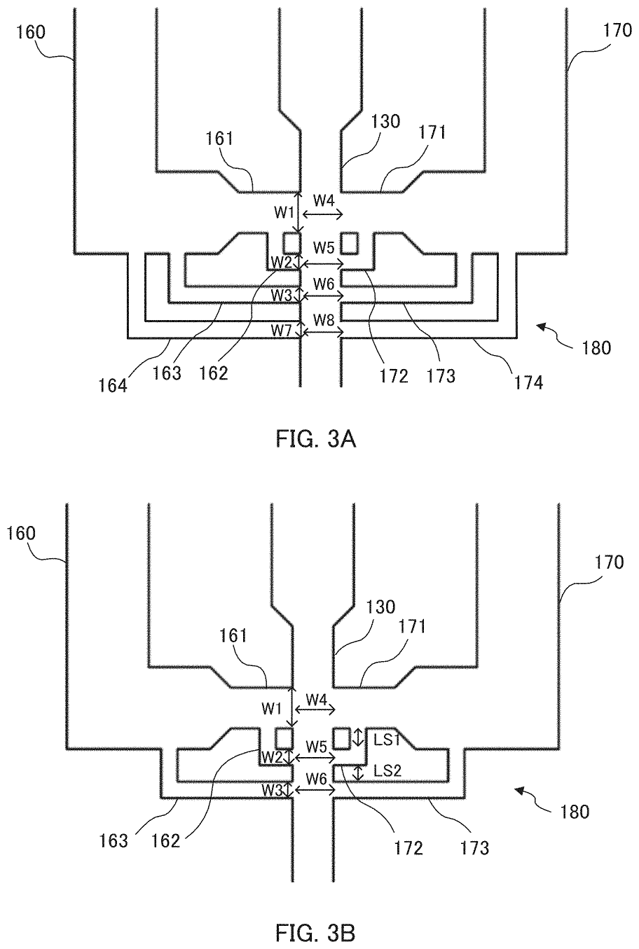

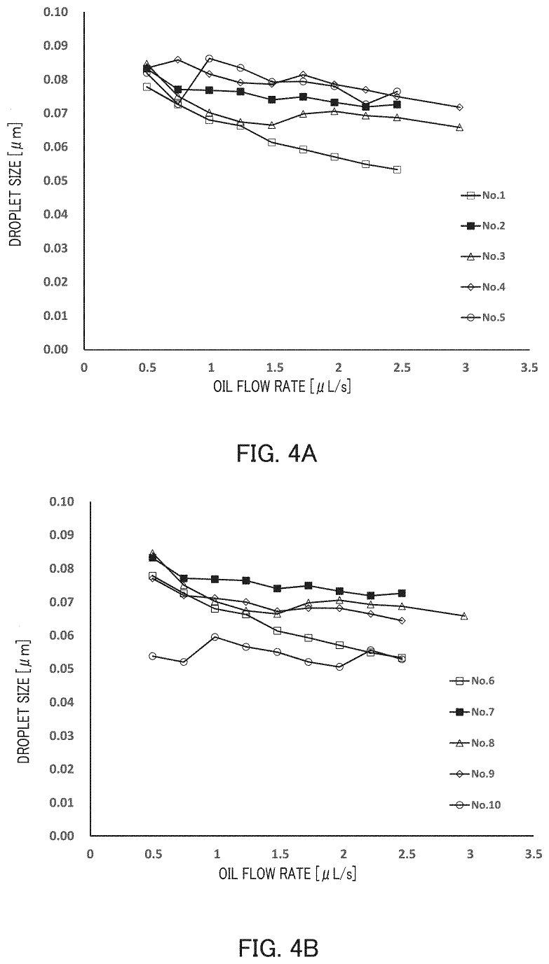

Thus, main channel 161 and sub channels 162 to 164 of second channel 160 open to one side surface of first channel 130, and main channel 171 and sub channels 172 to 174 of third channel 170 open to the other side surface of first channel 130. The opening of main channel 161 of second channel 160 and the opening of main channel 171 of third channel 170 are disposed to face each other (see FIGS. 2A to 3B). Similarly, the openings of sub channels 162 to 164 of second channel 160 and the respective openings of sub channels 172 to 174 of third channel 170 are disposed to face each other (see FIGS. 2A to 3B).

Second channel 160 and third channel 170 are connected to second liquid inlet 140 via second liquid common channel 150 in the present embodiment, but may be directly connected to second liquid inlet 140.

Droplet generator 180 is a junction of first channel 130, second channel 160 and third channel 170, and configured such that a second liquid flowing in second channel 160 and third channel 170 divides a first liquid flowing in first channel 130 into droplets. In droplet generator 180, the first liquid flowing in first channel 130 is divided by the second liquid flowing in second channel 160 and third channel 170, thereby generating a droplet of the first liquid in the second liquid. As described above, the opening of main channel 161 of second channel 160 and the opening of main channel 171 of third channel 170 are disposed to face each other in droplet generator 180. Similarly, the openings of sub channels 162 to 164 of second channel 160 and the respective openings of sub channels 172 to 174 of third channel 170 are disposed to face each other. Liquid handling device 100 according to the present embodiment has its main feature in the configuration of droplet generator 180. Droplet generator 180 will thus be separately described in detail.

Droplet channel 190 guides droplets generated in droplet generator 180 to droplet outlet 200. The upstream end of droplet channel 190 is connected to droplet generator 180, and the downstream end of droplet channel 190 is connected to droplet outlet 200. Droplet channel 190 may have any shape as long as a droplet can appropriately move therein. Droplet channel 190 is linear and disposed on the same straight line as first channel 130 in the present embodiment. Thus, it can also be considered that second channel 160 and third channel 170 join a linear channel composed of first channel 130 and droplet channel 190 at a boundary region of first channel 130 and droplet channel 190. The cross-sectional area of droplet channel 190 is not limited as long as droplets are not broken, and may be set appropriately according to the size of droplets to be generated. The width of droplet channel 190 is, for example, about 50μm to 300μm. The depth of droplet channel 190 is, for example, about 30μm to 100μm.

Droplet outlet 200 is a bottomed recess for housing the droplet moving through droplet channel 190. Droplet outlet 200 is formed, as described above, by blocking with a film one of the openings of the through hole formed in substrate 110. Droplet outlet 200 may have any shape and size as long as droplet outlet 200 can be reached from the outside to take out droplets. Examples of the shape of droplet outlet 200 include a cylindrical shape and a truncated cone shape. Droplet outlet 200 has a cylindrical shape in the present embodiment.

The method for using liquid handling device 100 will be briefly described. After a first liquid and a second liquid are housed in first liquid inlet 120 and second liquid inlet 140 respectively, the first liquid in first liquid inlet 120 and the second liquid in second liquid inlet 140 are moved to droplet generator 180 at a predetermined speed by an external force such as a pump. The second liquid flowing in second channel 160 and third channel 170 divides the first liquid flowing in first channel 130 in droplet generator 180, thereby generating a droplet. Droplets stay dispersed in the second liquid. The liquid containing the droplets moves in droplet channel 190 to be housed in droplet outlet 200, and becomes ready to be taken out.

(Configuration of Droplet Generator)

The configuration of droplet generator 180 will be described in the following. As described above, droplet generator 180 is a junction of first channel 130, second channel 160 and third channel 170.

FIGS. 2A and 2B are partially enlarged views illustrating an example of droplet generator 180 of liquid handling device 100. FIG. 2A illustrates the widths of respective openings of first channel 130, and main channel 161 and sub channels 162 and 163 of second channel 160 as W0 to W3. FIG. 2B illustrates the widths of first channel 130 at the individual junctions with both of second channel 160 and third channel 170 as W4 to W6.

As illustrated in FIG. 2A, droplet generator 180 is a junction of second channel 160 and third channel 170 with first channel 130, and configured such that a second liquid flowing in second channel 160 and third channel 170 divides a first liquid flowing in first channel 130 into droplets. In droplet generator 180, openings are disposed in such a way that the openings of main channel 161 and sub channels 162 and 163 of second channel 160 with respect to first channel 130 face the respective openings of main channel 171 and sub channels 172 and 173 of third channel 170 with respect to first channel 130. By disposing the opening of main channel 161 of second channel 160 and the opening of main channel 171 of third channel 170 with respect to first channel 130 so as to face each other, the size of generated droplets becomes less likely to change even when the flow rate of the second liquid flowing through second channel 160 and third channel 170 changes. Second channel 160 includes main channel 161, first sub channel 162 and second sub channel 163, and third channel 170 includes main channel 171, first sub channel 172 and second sub channel 173 in the present embodiment. The opening of main channel 161 of the second channel to first channel 130 is disposed in first channel 130 upstream from the opening of sub channels 162 and 163 of second channel 160 to first channel 130 (upper side in FIGS. 2A and 2B). The opening of main channel 171 of third channel 170 to first channel 130 is similarly disposed in first channel 130 upstream from the openings of sub channels 172 and 173 of third channel 170 to first channel 130 (upper side in FIGS. 2A and 2B).

In the present embodiment, second channel 160 is open to one side surface (left side in FIGS. 2A and 2B) of first channel 130, and third channel 170 is open to the other side surface (right side in FIGS. 2A and 2B) of first channel 130. The opening of main channel 161 of second channel 160 and the opening of main channel 171 of third channel 170 are disposed to face each other. The opening of first sub channel 162 of second channel 160 and the opening of first sub channel 172 of third channel 170 are similarly disposed to face each other. The opening of second sub channel 163 of second channel 160 and the opening of second sub channel 173 of third channel 170 are also disposed to face each other. In this mode, the opening of first sub channel 162 of second channel 160 is disposed in first channel 130 upstream from the opening of second sub channel 163 of second channel 160. Similarly in this mode, the opening of first sub channel 172 of third channel 170 is disposed in first channel 130 upstream from the openings of second sub channel 173 of third channel 170.

As illustrated in FIG. 2A, the width of the opening (hereinafter also referred to as “opening width”) of main channel 161 of second channel 160 to first channel 130 (the opening width of main channel 161 of second channel 160 is indicated by W1 in FIG. 2A) is preferably larger than the widths of the openings of first sub channel 162 and second sub channel 163 of second channel 160 to first channel 130 (the opening width of first sub channel 162 is indicated by W2, and the opening width of second sub channel 163 is indicated by W3 in FIG. 2A). More specifically, opening width W1 of main channel 161 of the second channel preferably differs from opening width W2 of first sub channel 162 and opening width W3 of second sub channel 163 by a length within the range of 25 to 50μm. The same feature applies to third channel 170. By making the opening widths of main channel 161 of second channel 160 and main channel 171 of third channel 170 larger than the opening widths of first sub channel 162 and second sub channel 163 of second channel 160 and the opening widths of first sub channel 172 and second sub channel 173 of third channel 170, it becomes possible to suppress the generation of a small droplet that occasionally occurs (see Experiment 1 of the example). This small droplet is completely different in size from the droplets that are normally generated, and has no particular effect on the accuracy of the analysis. Opening width W1 of main channel 161 of second channel 160 and the opening width of main channel 171 of third channel 170 are the same in the present embodiment. Opening width W2 of first sub channel 162 and opening width W3 of second sub channel 163 in second channel 160 are respectively the same as the opening widths of the first sub channel 172 and second sub channel 173 in third channel 170 in the present embodiment.

Opening width W2 of first sub channel 162 and opening width W3 of second sub channel 163 in second channel 160 with respect to first channel 130 are preferably each equal to or less than width W0 of first channel 130 in droplet generator 180. More specifically, opening width W2 of first sub channel 162 and opening width W3 of second sub channel 163 in second channel 160 preferably differ from width W0 of first channel 130 by a length within the range of 0 to 50μm. The same feature applies to third channel 170. By setting opening width W2 of first sub channel 162 and opening width W3 of second sub channel 163 in the second channel 160, and the opening width of first sub channel 172 and the opening width of second sub channel 173 in third channel 170 to be equal to or less than width W0 of first channel 130, the size of generated droplets becomes even less likely to change even when the flow rate of the second liquid flowing through second channel 160 and third channel 170 changes (see Experiment 1 of the example).

When second channel 160 includes a plurality of sub channels as in the present embodiment (sub channels of second channel 160 are indicated by 162 and 163 in FIG. 2A), it is preferred that the widths of the openings of sub channels 162 and 163 of second channel 160 to first channel 130 are substantially the same. More specifically, the maximum difference between the opening widths of sub channels 162 and 163 of second channel 160 is preferably within the range of 0 to 25μm. The same feature applies to third channel 170. By making the widths of sub channels 162 and 163 of second channel 160 substantially the same, and the opening widths of sub channels 172 and 173 of third channel 170 substantially the same, it becomes possible to suppress the generation of a small droplet that occasionally occurs (see Experiment 1 of the example).

As illustrated in FIG. 2B, it is preferred that widths W4, W5 and W6 are substantially the same. Here, W4 is a width of the first channel at the junction of first channel 130 with main channel 161 of second channel 160 and main channel 171 of third channel 170; W5 is a width of first channel 130 at the junction of first channel 130 with first sub channel 162 of second channel 160 and first sub channel 172 of third channel 170; and W6 is a width of first channel 130 at the junction of first channel 130 with second sub channel 163 of second channel 160 and second sub channel 173 of third channel 170. More specifically, the maximum difference between widths W4, W5 and W6 of first channel 130 is preferably within the range of 0 to 50μm. By making the widths (W4 to W6) of first channel 130 at individual junctions with the channels substantially the same in droplet generator 180, it becomes possible to suppress the generation of a small droplet that occasionally occurs (see Experiment 2 of the example).

FIGS. 3A and 3B are partially enlarged views illustrating examples of droplet generator 180 of liquid handling device 100. FIG. 3A shows a mode in which the number of sub channels is larger than that in the modes shown in FIGS. 2A, 2B and 3B. FIG. 3A illustrates the widths of respective openings of main channel 161 and sub channels 162 to 164 of second channel 160 as W1 to W3 and W7. FIG. 3A also illustrates the width of first channel 130 at the junction with main channel 161 of second channel 160 and main channel 171 of third channel 170 as W4, the widths at the independent junctions with sub channels 162 to 164 of second channel 160 and corresponding sub channels 172 to 174 of third channel 170 as W5, W6 and W8. FIG. 3B illustrates the widths of respective openings of main channel 161 and sub channels 162 and 163 of second channel 160 as W1 to W3. FIG. 3B also illustrates the width of first channel 130 at the junction with main channel 161 as W4, and the widths of first channel 130 at the junctions of respective sub channels 162 and 163 of second channel 160 as W5 and W6. FIG. 3B further illustrates the distance between the opening of main channel 161 and the opening of first sub channel 162 in second channel 160 as distance LS1, and the distance between the opening of first sub channel 162 and the opening of second sub channel 163 in second channel 160 as distance LS2.

The number of sub channels that join first channel 130 in each of second channel 160 and third channel 170 is not limited, but is preferably one, two or three, and more preferably one or two. By setting the number of sub channels that join first channel 130 in each of second channel 160 and third channel 170 to two or more, the size of generated droplets becomes even less likely to change even when the flow rate of the second liquid flowing through second channel 160 and third channel 170 changes (see Experiment 3 of the example). FIG. 3A illustrates second channel 160 having three sub channels 162 to 164, and third channel 170 also having three sub channels 172 to 174. FIG. 3B illustrates second channel 160 having two sub channels 162 and 163, and third channel 170 also having two sub channels 172 and 173.

When second channel 160 and third channel 170 each include a plurality of sub channels, the distance between the opening of main channel 161 and the opening of first sub channel 162 disposed on the most upstream side, and the distances between the openings of sub channels 162 to 164 are preferably small to some extent in second channel 160. More specifically, the distance between the opening of main channel 161 and the opening of first sub channel 162 disposed on the most upstream side, and the distances between the openings of sub channels 162 to 164 are preferably all less than 100μm in second channel 160. The same feature applies to third channel 170. When, for example, second channel 160 includes two sub channels as illustrated in FIG. 3B (sub channels of second channel 160 are indicated by 162 and 163 in FIG. 3B), distance LS1 between the opening of main channel 161 and the opening of first sub channel 162 in second channel 160, and distance LS2 between the opening of first sub channel 162 and the opening of second sub channel 163 in second channel 160 are preferably all less than 100μm. Similarly, when third channel 170 includes two sub channels (sub channels of third channel 170 are indicated by 172 and 173 in FIG. 3B), the distance between the opening of main channel 171 and the opening of first sub channel 172 in third channel 170, and the distance between the opening of first sub channel 172 and the opening of second sub channel 173 in third channel 170 are preferably less than 100μm. By setting the distances to less than 100μm, it becomes possible to suppress the generation of a small droplet that occasionally occurs (see Experiment 4 of the example).

(Effects)

Liquid handling apparatus 100 according to the present invention includes second channel 160 and third channel 170 each including a main channel and at least one sub channel on the downstream side, and thus can stably generate droplets of a desired size even when the flow rate of a second liquid flowing in second channel 160 and third channel 170 changes.

The present embodiment describes a mode with second channel 160 and third channel 170 connected to one second liquid inlet 140, but the present invention is not limited to this mode. Liquid handling device 100 may, for example, include two second liquid inlets 140 to which second channel 160 and third channel 170 are respectively connected.

Hereinafter, the present invention will be described in detail with reference to examples, but the present invention is not limited to these examples.

### EXAMPLES

[Experiment 1]

Nos. 1 to 5 liquid handling devices 100 were produced by changing opening width W0 of first channel 130, opening widths W1 of main channels 161 and 171, opening widths W2 of first sub channels 162 and 172, and opening widths W3 of second sub channels 163 and 173 in droplet generator 180 illustrated in FIG. 2A as shown in Table 1. The depths of first channel 130, second channel 160, and third channel 170 were all set to 30μm.

TABLE 1

| | First | Main | First sub | Second sub |
|---|---|---|---|---|
| | channel W0 | channel W1 | channel W2 | channel W3 |
| No. | (mm) | (mm) | (mm) | (mm) |
| 1 | 0.075 | 0.1 | — | — |
| 2 | 0.1 | 0.1 | 0.04 | 0.04 |
| 3 | 0.1 | 0.05 | 0.05 | 0.05 |
| 4 | 0.1 | 0.05 | 0.075 | 0.1 |
| 5 | 0.1 | 0.1 | 0.075 | 0.05 |

For each liquid handling device, the relationship between the flow rate of the second liquid flowing in second channel 160 and third channel 170 and the size of generated droplets was analyzed. Pure water was used as the first liquid flowing in first channel 130. Droplet Generator Oil for Probes (manufactured by Bio-Rad Laboratories, Inc) was used as the second liquid flowing in second channel 160 and third channel 170. The flow rate of the first liquid flowing in first channel 130 is fixed at 0.198μL/s, and the flow rate of the second liquid flowing in second channel 160 and third channel 170 (hereinafter, also referred to as “oil flow rate”) was varied within the range of 0.0492μL/s to 3.444μL/s. FIG. 4A shows the experimental results.

As shown in FIG. 4A, the droplet size decreased significantly as the oil flow rate increased in No. 1 liquid handling device including no sub channel. In Nos. 2 to 5 liquid handling devices including sub channels, meanwhile, the droplet size did not change significantly even when the oil flow rate increased. This result shows that even when the oil flow rate changes to some extent, droplets of a desired size can be stably generated by providing at least one sub channel in addition to a main channel.

In No. 4 liquid handling device (W1<W2<W3) and No. 5 liquid handling device (W1>W2>W3), the droplet size did not change significantly even when the oil flow rate increased, but a droplet with a significantly small size was generated occasionally. Also in No. 3 liquid handling device (W1=W2=W3), a droplet with a significantly small size was generated occasionally. On the other hand, no droplet with a significantly small size was generated in No. 2 liquid handling device (W1>W2=W3). This result shows that the following is preferred for suppressing the generation of a droplet with a significantly small size: opening widths W1 of main channels 161 and 171 are larger than opening widths W2 of first sub channels 162 and 172 or opening widths W3 of second sub channels 163 and 173; and opening widths W2 of first sub channels 162 and 172 are substantially the same as opening widths W3 of second sub channels 163 and 173.

[Experiment 2]

Nos. 6 to 10 liquid handling devices 100 were produced by changing width W4 of first channel 130 at the junction with main channels 161 and 171, width W5 of first channel 130 at the junction with first sub channels 162 and 172, and width W6 of first channel 130 at the junction with second sub channels 163 and 173 illustrated in FIG. 2B as shown in Table 2. The depths of first channel 130, second channel 160, and third channel 170 were all set to 30μm.

TABLE 2

| | Main channel | | First sub channel | | Second sub channel | |
|---|---|---|---|---|---|---|
| | W1 | W4 | W2 | W5 | W3 | W6 |
| No. | (mm) | (mm) | (mm) | (mm) | (mm) | (mm) |
| 6 | 0.1 | 0.1 | — | — | — | — |
| 7 | 0.1 | 0.1 | 0.04 | 0.1 | 0.04 | 0.1 |
| 8 | 0.05 | 0.1 | 0.05 | 0.1 | 0.05 | 0.1 |
| 9 | 0.05 | 0.1 | 0.05 | 0.075 | 0.05 | 0.05 |
| 10 | 0.05 | 0.05 | 0.05 | 0.075 | 0.05 | 0.1 |

For each liquid handling device, the relationship between the flow rate of the second liquid flowing in second channel 160 and third channel 170 and the size of generated droplets was analyzed. The type and the flow rate of the first liquid in use, and the type and the flow rate of the second liquid in use are the same as in Experiment 1. FIG. 4B shows the experimental results.

As shown in FIG. 4B, the droplet size decreased significantly as the oil flow rate increased in No. 6 liquid handling device including no sub channel. In Nos. 7 to 10 liquid handling devices including sub channels, meanwhile, the droplet size did not change significantly even when the oil flow rate increased. This result shows that even when the oil flow rate changes to some extent, droplets of a desired size can be stably generated by providing at least one sub channel in addition to a main channel.

In No. 9 liquid handling device (W4>W5>W6) and No. 10 liquid handling device (W4<W5<W6), the droplet size did not change significantly even when the oil flow rate increased, but a droplet with a significantly small size was generated occasionally. On the other hand, no droplet with a significantly small size was generated in No. 7 liquid handling device (W4=W5=W6) and No. 8 liquid handling device (W4=W5=W6). This result shows that the following is preferred for suppressing the generation of a droplet with a significantly small size: widths W4 to W6 of first channel 130 at the respective junctions with channels are substantially the same.

[Experiment 3]

Nos. 11 to 14 liquid handling devices 100 were produced by changing the number of sub channels as shown in Table 3 as illustrated in FIGS. 3A and 3B. The depths of first channel 130, second channel 160, and third channel 170 were all set to 30μm.

TABLE 3

| | | | First sub | | Second sub | | Third sub | |
|---|---|---|---|---|---|---|---|---|
| | Main channel | | channel | | channel | | channel | |
| | W1 | W4 | W2 | W5 | W3 | W6 | W7 | W8 |
| No. | (mm) | (mm) | (mm) | (mm) | (mm) | (mm) | (mm) | (mm) |
| 11 | 0.1 | 0.1 | — | — | — | — | — | — |
| 12 | 0.1 | 0.1 | 0.04 | 0.1 | 0.04 | 0.1 | — | — |
| 13 | 0.05 | 0.1 | 0.05 | 0.1 | 0.05 | 0.1 | — | — |
| 14 | 0.05 | 0.1 | 0.05 | 0.1 | 0.05 | 0.1 | 0.05 | 0.1 |

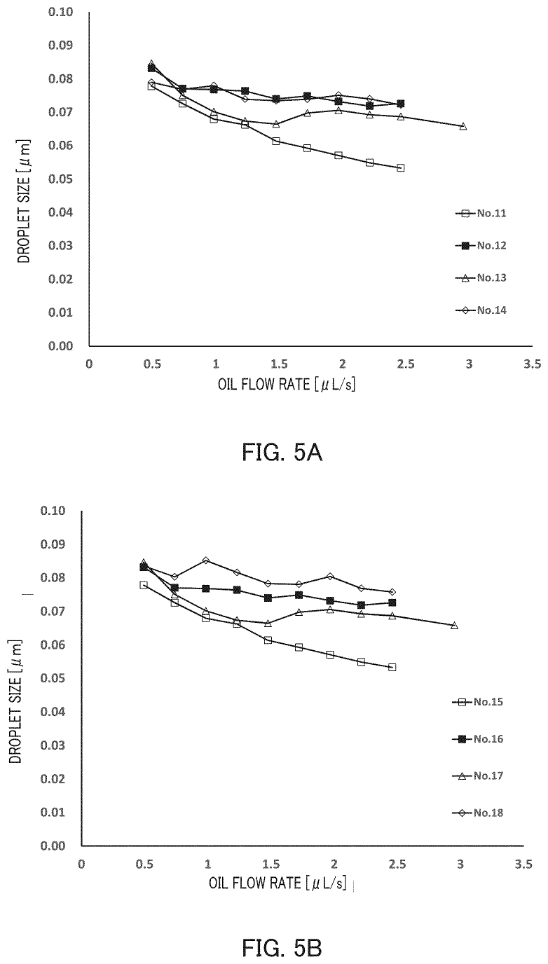

For each liquid handling device, the relationship between the flow rate of the second liquid flowing in second channel 160 and third channel 170 and the size of generated droplets was analyzed. The type and the flow rate of the first liquid in use, and the type and the flow rate of the second liquid in use are the same as in Experiment 1. FIG. 5A shows the experimental results.

As shown in FIG. 5A, the droplet size decreased significantly as the oil flow rate increased in No. 11 liquid handling device including no sub channel. In Nos. 12 to 14 liquid handling devices including sub channels, meanwhile, the droplet size did not change significantly even when the oil flow rate increased. This result shows that even when the oil flow rate changes to some extent, droplets of a desired size can be stably generated by providing at least one sub channel in addition to a main channel.

There was less change in droplet size in No. 14 liquid handling device than in Nos. 12 and 13 liquid handling devices. Here, No. 14 liquid handling device includes second channel 160 and third channel 170 each including three sub channels (sub channels 162 to 164 of second channel 160 and sub channels 172 to 174 of third channel 170) and Nos. 12 and 13 liquid handling devices include second channel 160 and third channel 170 each including two sub channels (sub channels 162 and 163 of second channel 160 and sub channels 172 and 173 of third channel 170). On the other hand, No. 14 liquid handling device with second channel 160 and third channel 170 each including three sub channels generated more droplets with a significantly small size than Nos. 12 and 13 liquid handling devices with second channel 160 and third channel 170 each including two sub channels do. This result shows that a larger number of sub channels is preferred for stabilizing the size of droplets, but a not too large number of sub channels is preferred for suppressing the generation of a droplet with a significantly small size.

[Experiment 4]

Nos. 15 to 18 liquid handling devices 100 were produced by changing distance LS1 between the opening of main channel 161 (171) and the opening of first sub channel 162 (172), and distance LS2 between the opening of first sub channel 162 (172) and the opening of second sub channel 163 (173) illustrated in FIG. 3B as shown in Table 4. The depths of first channel 130, second channel 160, and third channel 170 were all set to 30μm.

TABLE 4

| | | | First sub | | Second sub | | Distance | |
|---|---|---|---|---|---|---|---|---|
| | Main channel | | channel | | channel | | between openings | |
| | W1 | W4 | W2 | W5 | W3 | W6 | LS1 | LS2 |
| No. | (mm) | (mm) | (mm) | (mm) | (mm) | (mm) | (mm) | (mm) |
| 15 | 0.1 | 0.1 | — | — | — | — | — | — |
| 16 | 0.1 | 0.1 | 0.04 | 0.1 | 0.04 | 0.1 | 0.05 | 0.04 |
| 17 | 0.05 | 0.1 | 0.05 | 0.1 | 0.05 | 0.1 | 0.05 | 0.05 |
| 18 | 0.05 | 0.1 | 0.05 | 0.1 | 0.05 | 0.1 | 0.1 | 0.1 |

For each liquid handling device, the relationship between the flow rate of the second liquid flowing in second channel 160 and third channel 170 and the size of generated droplets was analyzed. The type and the flow rate of the first liquid in use, and the type and the flow rate of the second liquid in use are the same as in Experiment 1. FIG. 5B shows the experimental results.

As shown in FIG. 5B, the droplet size decreased significantly as the oil flow rate increased in No. 15 liquid handling device including no sub channel. In Nos. 16 to 18 liquid handling devices including sub channels, meanwhile, the droplet size did not change significantly even when the oil flow rate increased. This result shows that even when the oil flow rate changes to some extent, droplets of a desired size can be stably generated by providing at least one sub channel in addition to a main channel.

No. 18 Liquid handling device having distances LS1 and LS2 of 0.1 mm between the openings was capable of stably generating droplets with a large size compared to Nos. 16 and 17 liquid handling devices having distances LS1 and LS2 between the openings in the range of 0.04 to 0.05 mm. On the other hand, No. 18 liquid handling device having distances LS1 and LS2 of 0.1 mm between the openings generated more droplets with a significantly small size than Nos. 16 and 17 liquid handling devices having distances LS1 and LS2 between the openings in the range of 0.04 to 0.05 mm do. This result shows that a larger length for distances LS1 and LS2 between the openings is preferred for stably generating droplets with a large size, but a length less than 0.1 mm for distances LS1 and LS2 between the openings is preferred for suppressing the generation of a droplet with a significantly small size.

[Experiment 5]

By changing the number of sub channels as illustrated in FIGS. 3A and 3B, the following liquid handling devices were produced: No. 19 liquid handling device 100 (not illustrated) including no sub channel, No. 20 liquid handling device 100 (not illustrated) with second channel 160 and third channel 170 each including one sub channel, and No. 21 liquid handling device 100 with second channel 160 and third channel 170 each including two sub channels (sub channels 162 and 163 of second channel 160 and sub channels 172 and 173 of third channel 170). The depths of first channel 130, second channel 160, and third channel 170 were all set to 50μm.

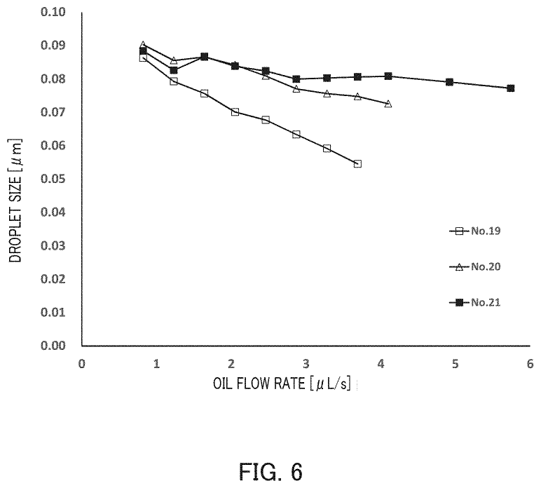

For each liquid handling device, the relationship between the flow rate of the second liquid flowing in second channel 160 and third channel 170 and the size of generated droplets was analyzed. The type of the second liquid is the same as in Experiment 1. As the first liquid, 0.1% aqueous solution of surfactant (Tween 20) was used. The flow rate of the first liquid was set to 0.328μL/s, and the flow rate of the second liquid (oil flow rate) was set to a value within the range of 0.82μL/s to 5.74μL/s. FIG. 6 shows the experimental results.

As shown in FIG. 6, the droplet size decreased significantly as the oil flow rate increased in No. 19 liquid handling device including no sub channel. In No. 20 liquid handling device with second channel 160 and third channel 170 each including one sub channel, and No. 21 liquid handling device with the channels each including two sub channels, meanwhile, the droplet size did not change significantly even when the oil flow rate increased. In particular, the droplet size changed little even when the oil flow rate increased in No. 21 liquid handling device with the channels each including two sub channels. This result shows that even when a first liquid with a surfactant added therein is used and the oil flow rate changes to some extent, droplets of a desired size can be stably generated by providing at least one sub channel in addition to a main channel. In addition, none of Nos. 19 to 21 liquid handling devices generated a droplet with a significantly small size. This result shows that, provided that there is no disadvantage in adding a surfactant to a first liquid, the addition of the surfactant can suppress the generation of a droplet with a significantly small size.

This application claims priority based on Japanese Patent Application No. 2018-036453, filed on Mar. 1, 2018, the entire contents of which including the specification and the drawings are incorporated herein by reference.

### INDUSTRIAL APPLICABILITY

The present invention is particularly advantageous as a liquid handling device used in, for example, clinical analyses.

### REFERENCE SIGNS LIST

100 Liquid handling device

110 Substrate

120 First liquid inlet

130 First channel

140 Second liquid inlet

150 Second liquid common channel

160 Second channel

161 Main channel of second channel

162 First sub channel of second channel

163 Second sub channel of second channel

164 Third sub channel of second channel

170 Third channel

171 Main channel of third channel

172 First sub channel of third channel

173 Second sub channel of third channel

174 Third sub channel of third channel

180 Droplet generator

190 Droplet channel

200 Droplet outlet

W0 Width of first channel

W1 Opening width of main channel of second channel

W2, W3, W7 Opening width of sub channel of second channel

W4, W5, W6, W8 Width of first channel

LS1 Distance between openings of main channel and first sub channel of second channel

LS2 Distance between openings of first sub channel and second sub channel

In the claims:

1. A liquid handling device comprising:
a first channel that allows a first liquid to flow through;
a second channel that allows a second liquid to move through, the second channel joining the first channel;
a third channel that allows the second liquid to move through, the third channel joining the first channel; and
a droplet generator configured such that the second liquid flowing in the second channel and the third channel divides the first liquid flowing in the first channel into droplets, the droplet generator being a junction of the second channel and the third channel with the first channel,
wherein
the second channel and the third channel each include a main channel and a sub channel on a downstream side,
an opening of the main channel of the second channel with respect to the first channel is disposed to face an opening of the main channel of the third channel with respect to the first channel, and
an opening of the sub channel of the second channel with respect to the first channel is disposed to face an opening of the sub channel of the third channel with respect to the first channel.

2. The liquid handling device according to claim 1, wherein:
in the droplet generator, the openings of the main channels of the second channel and the third channel are disposed in the first channel upstream from the openings of the sub channels of the second channel and the third channel, respectively, and
in the droplet generator, widths of the openings of the main channels of the second channel and the third channel are larger than widths of the openings of the sub channels of the second channel and the third channel, respectively.

3. The liquid handling device according to claim 1, wherein, in the droplet generator, the widths of the openings of the sub channels of the second channel and the third channel are each equal to or less than a width of the first channel.

4. The liquid handling device according to claim 1, further comprising:
a second liquid inlet for introducing the second liquid,
wherein the second channel and the third channel are both connected to the second liquid inlet.

5. The liquid handling device according to claim 1, wherein:
a maximum difference between a first width and a second width is 100μm or less, the first width being a width of the first channel at a junction of the first channel with the main channels of the second channel and the third channel, the second width being a width of the first channel at a junction of the first channel with the sub channels of the second channel and the third channel.

6. The liquid handling device according to claim 1, wherein:
the sub channels of the second channel and the third channel each include two or more sub channels;
a distance between the opening of the main channel of the second channel and the opening of the sub channel of the second channel is less than 100μm, and a distance between openings of the two or more sub channels of the second channel is less than 100μm; and
a distance between the opening of the main channel of the third channel and the opening of the sub channel of the third channel is less than 100μm, and a distance between openings of the two or more sub channels of the third channel is less than 100μm.
